(19) United States
(12) Patent Application Publication
(10) Pub. No.: US 2005/0001688 A1
(43) Pub. Date: Jan. 6, 2005

(54) System and device for calibrating oscillator charateristic curve

(75) Inventor: Hann-Wen Lin, Taipei (TW)

Correspondence Address: TROXELL LAW OFFICE PLLC, Suite 1404, 5205 Leesburg Pike, Falls Church, VA, 22041, US

(73) Assignee: ALi Corporation

(21) Appl. No.: 10/793,779

(22) Filed: Mar. 8, 2004

(30) Foreign Application Priority Data
Jul. 1, 2003 (TW) 92117908

(51) Int. Cl. H03L 7/00

(52) U.S. Cl. 331/16

(57) ABSTRACT

The present invention relates to a system and an device for calibrating oscillator characteristic curve, more particularly, to a system and device that are capable of making an evaluation to determine whether it is necessary to change the characteristic curve of the oscillator by means of a calibration device; if so, the device will send a calibration signal to a calibration circuit for changing the circuit characteristic thereof so as to choose an appropriate characteristic curve of the oscillator. The present invention can calibrate the frequency characteristic curve of the oscillator automatically so as to avoid being affected by the manufacture process and temperature. Furthermore, the manual adjustment is no longer required before every shipping that not only can reduce the uncertainty caused by manual adjustment, but also can reduce labor cost. Besides, the present invention can calibrate the frequency characteristic curve of the oscillator at any time so that the quality of the product according to the present invention can be assured even after shipping. The foregoing advantages are not achievable using the prior art.

### BACKGROUND OF THE INVENTION

(a). Field of the Invention

The present invention relates to a system and an device for calibrating oscillator characteristic curve, more particularly, to a system and device that are capable of making an evaluation to determine whether it is necessary to change the characteristic curve of the oscillator by means of a calibration device; if so, the device will send a calibration signal to a calibration circuit for changing the circuit characteristic thereof so as to choose an appropriate characteristic curve of the oscillator.

(b). Description of the Prior Arts

Oscillator is a common component used in radio communication system of other high frequency systems, moreover, oscillator as a component even can be found in circuits relating to timing or counting. Following the progress of technology, frequencies used in human society become higher and higher. In this regard, a high frequency voltage control oscillator (VCO) and frequency synthesizer are needed in the radio communication system. or other high frequency system for generating a carrier wave. Please refer to FIG. 1, which is an operation chart showing the characteristic curve of the high frequency voltage control oscillator. Basing on the characteristic curve of the VCO as seen in FIG. 1, the VCO will pinpoint and output a frequency corresponding to the voltage of an input signal. However, the characteristic curve of the high frequency voltage control oscillator will be affected by manufacture process and temperature in a way that the frequency synthesizer can not lock on the correct frequency. The foregoing situation will become even sever while operating in high frequency.

Currently, there are two methods that can overcome the influences of manufacture process and temperature on the frequency of VCO. One of the methods is to increase the operation range of the frequency of the VCO to an extent that the operation range can overbear the effect caused by the manufacture process and temperature, i.e. increase the interval between F_{H} and F_{I} of FIG. 1. But the method will cause the phase noise of both the VCO and the frequency synthesizer to increase and consequently reduce the quality of output signals. Please refer to FIG. 2A, which is an ideal characteristic diagram of power to frequency. Generally, an impulse is desired in the power to frequency diagram as seen in FIG. 2A. Please refer to FIG. 2B, which is a characteristic diagram of power to frequency after enlarging the operation range of VCO. As seen in FIG. 2B, it is obvious that a power attenuation is happening which is disadvantageous to the whole system.

Another method for solving the foregoing problem is by adding a plurality of capacitors to the VCO. The VCO having a plurality of capacitors can change the frequency band of the VCO using the loading generated by turning on/off of the capacitors. Please refer to FIG. 3, which is a characteristic curve of a VCO connecting to three capacitors of different capacitances. The foregoing method can change the position of the characteristic curve in the power to frequency diagram through manually adjusting the number of capacitors connected so as to come up with an appropriate curve eventually. Although the forgoing method can avoid the need to increase the operation range of the VCO so as to prevent the phase noise of the synthesizer from increasing, the manual adjustment is required before every shipping which is very troublesome, and the adjustment of VCO after shipping is impossible to proceed even when the characteristic curve had shifted from the proper position because of the working environment.

To sum up, the methods used for adjusting operation frequency will cause the signal quality to degrade that consequently will have effect on the following operations of the system; moreover, the method using capacitors to change the characteristic curve of a VCO can be applied only once on the VCO. Thus, a new method is needed to improve the aforementioned shortcomings.

### SUMMARY OF THE INVENTION

The primary object of the present invention is to provide a system and a device for automatically calibrating oscillator characteristic curve.

Another object of the present invention is to provide a system and a device that is capable of calibrating oscillator characteristic curve at any time.

In order to achieve the foregoing object, the present invention provides a system for calibrating oscillator characteristic curve, comprising:
a power supply device, which is capable of generating a control signal;
an oscillator, connecting to the power supply device, which receives the control signal and uses thereof for generating an output frequency according to the characteristic curve of the oscillator;
a calibration device, connecting to the power supply device, which receives the control signal and uses thereof for making an evaluation to determine whether the characteristic curve of the oscillator requires to be changed so as to output a calibration signal accordingly; and
a calibration circuit, coupled to the oscillator, wherein the circuit characteristic of the calibration circuit will be changed in accordance to the calibration signal and thereafter further affects the characteristic curve of the oscillator.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits and advantages of the preferred embodiments of the present invention will be readily understood by the accompanying drawings and detailed descriptions, wherein:

FIG. 1 is an operation chart showing the characteristic curve of the voltage control oscillator.

FIG. 2A is an ideal characteristic diagram of power to frequency.

FIG. 2B is a characteristic diagram of power to frequency after enlarging the operation range of voltage control oscillator.

FIG. 3 is a characteristic curve of a voltage control oscillator connecting to three capacitors of different capacitances.

FIG. 4 is an architecture diagram showing the system of the present invention.

FIG. 5 is an embodiment of the calibration device according to the present invention.

### DETAILED DESCRIPTION OF THE PRESENT INVENTION

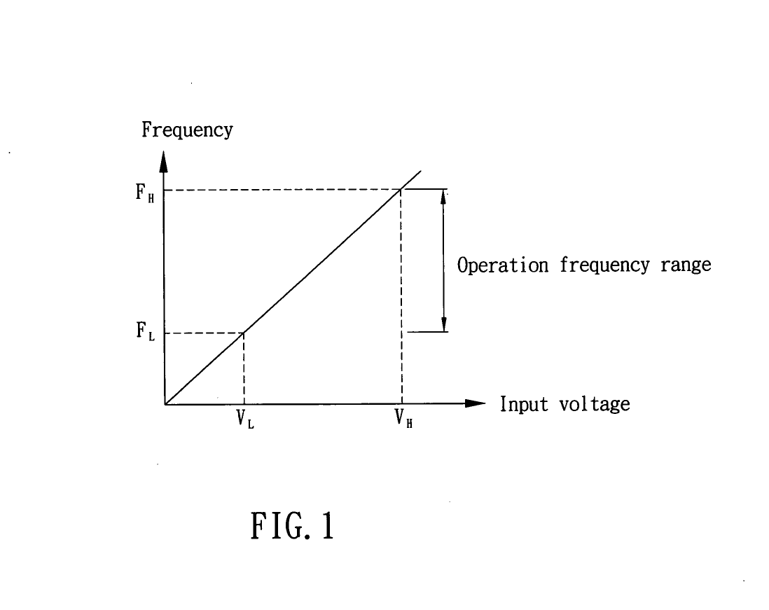

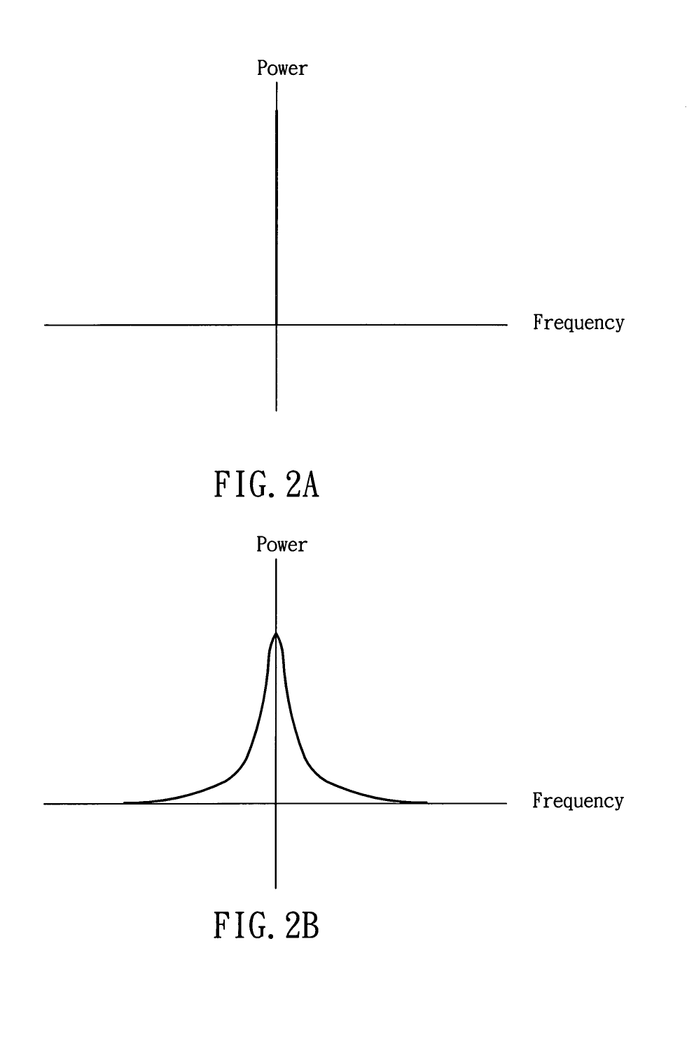

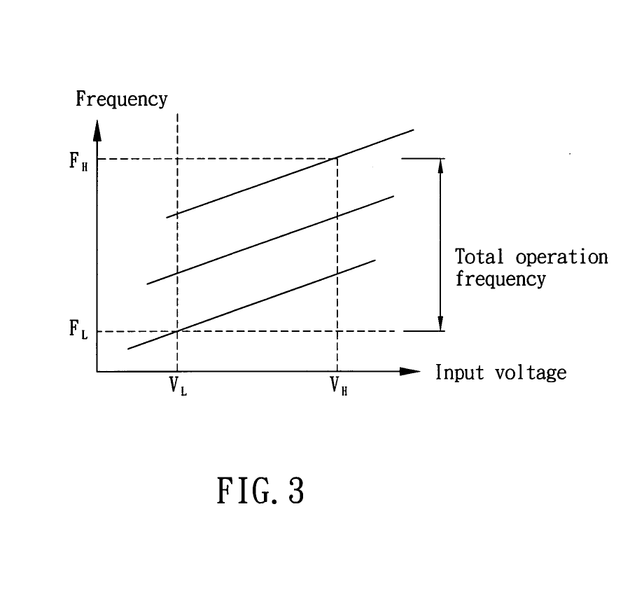

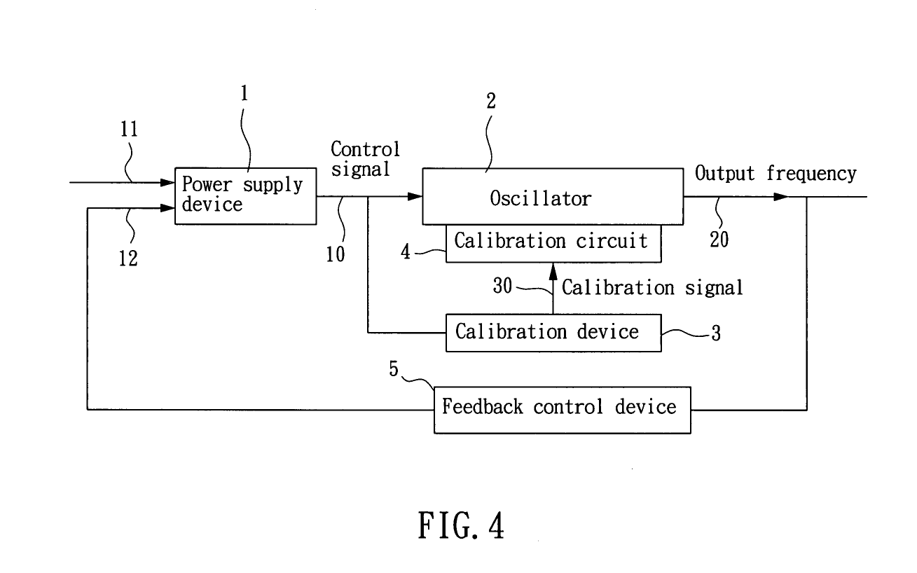

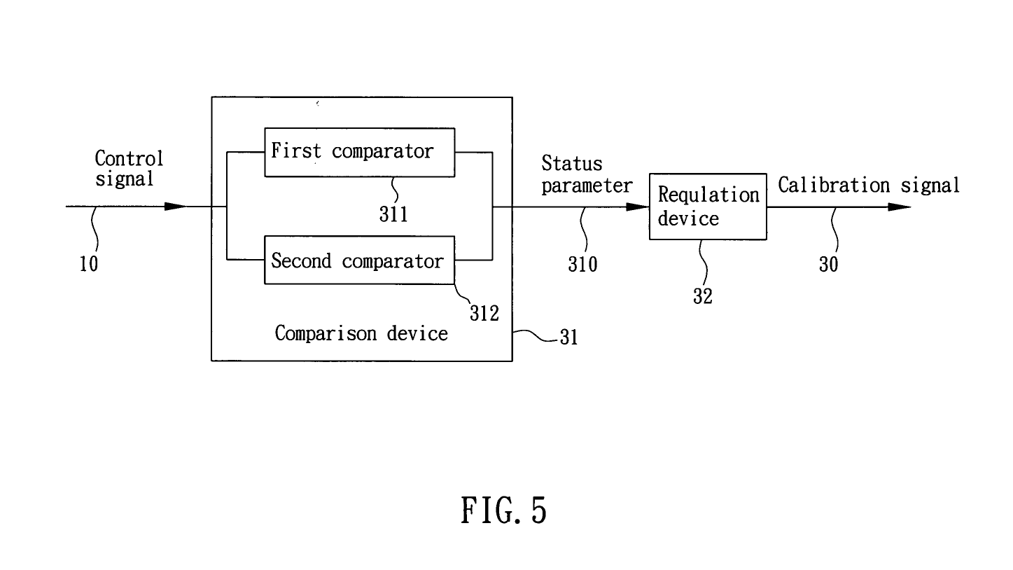

The following embodiments will illustrate the device and the method for processing the digital image of the present invention in detail. Please refer to FIG. 4, which is an architecture diagram showing a system of the present invention. The system of the present invention comprises:
a power supply device 1, for generating a control signal 10. In an embodiment of the present invention, the power supply device 1 will generate a control signal 10 according to a reference frequency 11 and a feedback frequency 12. In another embodiment of the present invention, the power supply device 1 is composed of a frequency comparator and a low-pass filter, wherein when the frequency synthesizer locks on to a certain frequency, i.e. PLL lock, the low-pass filter will output a control signal 10;
an oscillator 2, connecting to the power supply device 1, which receives the control signal 10 and uses thereof for generating an output frequency 20 according to the characteristic curve of the oscillator 2. That is, the oscillator will choose an output frequency 20 corresponding to the control signal 10 to be used in a posterior circuit according to the characteristic curve of FIG. 1 or FIG. 3. In an embodiment of the present invention, the oscillator 2 can be a voltage control oscillator (VCO), and the same time, the control signal is a voltage signal.
a calibration device 3, connecting to the power supply device 1, which receives the control signal 10 and uses thereof for making an evaluation to determine whether the characteristic curve of the oscillator 2 requires to be changed so as to output a calibration signal 30 accordingly. The calibration device 3 will make an evaluation to determine whether the characteristic curve is appropriate according to the information contained in the control signal 10. In an embodiment of the present invention, the evaluation is being made to determine whether the voltage of the control signal 10 is within a certain range? If so, which means that the operation frequency is working within a normal scope, thus, the characteristic curve is appropriate; if not, the characteristic curve will be adjusted to enable the operation frequency to work within the normal scope. Please refer to FIG. 5, which is an embodiment of the calibration device 3 according to the present invention. The calibration device 3 comprises:
   a comparison device 31, which receives a control signal 10 and compares the signal 10 with a condition so as to generate a status parameter 310. In an embodiment of the present invention, the comparison device 31 is composed of a first comparator 311 and a second comparator 312, wherein the first comparator 311 compares the control signal 10 with the upper bound of the normal voltage operation range, and the second comparator 312 compares the control signal 10 with the lower bound of the normal voltage operation range, moreover, the results of the two comparators are integrated into the status parameter 310.
   a regulation device 32, connecting to the comparison device 31, which regulates a counting value and generates a calibration signal 30 according to the status parameter 310. The regulation device 32 can be a counter. Assuming a predefined calibration signal 30 is set to be 8, if the status parameter is too high, then the calibration signal 30 will be reduced to 7; if the status parameter is too low, then the calibration signal 30 will be increased to 9; and if the status parameter is appropriate, then the calibration signal 30 remains the same.
   a calibration circuit 4, coupled to the oscillator 2, wherein the circuit characteristic of the calibration circuit is changed in accordance to the calibration signal 30 and thereafter affects the characteristic curve of the oscillator 2. In an embodiment of the present invention, the calibration circuit 4 is coupled to the oscillator 2 and is composed of a plurality of parallel-connected capacitors. The foregoing calibration circuit achieves the object of auto-adjustment by changing the number of the parallel-connected capacitors to change the circuit characteristic of the oscillator and further change the position of the characteristic curve of the oscillator according to the calibration signal 30. Normally, the more parallel-connected capacitors within the calibration circuit 4, the more adjustable stages exist in the system that the system will have a better control capability. The calibration circuit can be either a built-in component of the oscillator, or an external device coupled to the oscillator.

In a preferred embodiment of the present invention, the system of the present invention further comprises a feedback control device 5, which is connected to the oscillator 2 for receiving the output frequency 20 to proceed with feedback control by means of generating and sending the feedback frequency 12 to the power supply device 1. The power supply device 1 then can change the control signal 10 according to the reference frequency 11 and the feedback frequency 12 so that not only the object of feedback control can be achieved, but also can monitor the system at all time. In an embodiment of the present invention, the feedback control device can be a prescaler.

To sum up, the present invention is an improvement over the aforementioned second method that utilizes a plurality of capacitors. The present invention can calibrate the frequency characteristic curve of the oscillator automatically so as to avoid being affected by the manufacture process and temperature. Furthermore, the manual adjustment is no longer required before every shipping that not only can reduce the uncertainty caused by manual adjustment, but also can reduce labor cost. Besides, the present invention can calibrate the frequency characteristic curve of the oscillator at any time so that the quality of the product according to the present invention can be assured even after shipping. The foregoing advantages are not achievable using the prior art.

While the present invention has been shown and described with reference to a preferred embodiment thereof, and in terms of the illustrative drawings, it should be not considered as limited thereby. Various possible modification, omission, and alterations could be conceived of by one skilled in the art to the form and the content of any particular embodiment, without departing from the scope and the sprit of the present invention.

1. A system for calibrating oscillator characteristic curve, comprising: a power supply device, which is capable of generating a control signal;
an oscillator, connecting to the power supply device, which receives the control signal and uses thereof for generating an output frequency according to the characteristic curve of the oscillator;
a calibration device, connecting to the power supply device, which receives the control signal and uses thereof for making an evaluation to determine whether the characteristic curve of the oscillator requires to be changed so as to output a calibration signal accordingly; and
a calibration circuit, coupled to the oscillator, wherein the circuit characteristic of the calibration circuit will be changed in accordance to the calibration signal and thereafter affects the characteristic curve of the oscillator.

2. The system of claim 1, wherein the oscillator is a voltage control oscillator.

3. The system of claim 2, wherein the control signal is a voltage signal.

4. The system of claim 1, further comprising a feedback control device, which is connected to the oscillator for receiving the output frequency to proceed with feedback control by means of generating and sending the feedback frequency to the power supply device.

5. The system of claim 4, wherein the feedback control device is a prescaler.

6. The system of claim 1, wherein the calibration device further comprising:
a comparison device, which receives the control signal and compares the signal with a condition so as to generate a status parameter;
a regulation device, connecting to the comparison device, which regulates a counting value and generates the calibration signal according to the status parameter.

7. The system of claim 1, wherein the calibration circuit can be composed of at least one capacitor.

8. The system of claim 1, wherein the calibration circuit can be composed of a plurality of parallel-connected capacitors.

9. The system of claim 1, wherein the calibration circuit can be a built-in component of the oscillator.

10. A device for calibrating oscillator characteristic curve, which calibrate the characteristic curve of the oscillator by means of changing the circuit characteristic of the oscillator, comprising:
a comparison device, which receives the control signal and compares the signal with a condition so as to generate a status parameter;
a regulation device, connecting to the comparison device, which regulates a counting value and generates the calibration signal according to the status parameter; and
a calibration circuit, coupled to the oscillator, wherein the circuit characteristic of the calibration circuit will be changed in accordance to the calibration signal and thereafter further affects the characteristic curve of the oscillator.

11. The device of claim 10, wherein the oscillator is a voltage control oscillator.

12. The device of claim 11, wherein the control signal is a voltage signal.

13. The device of claim 10, wherein the calibration circuit can be composed of at least one capacitor.

14. The device of claim 10, wherein the calibration circuit can be composed of a plurality of parallel-connected capacitors.

15. The device of claim 10, wherein the calibration circuit can be a built-in component of the oscillator.
